(19) United States
(12) Patent Application Publication
(10) Pub. No.: US 2025/0234477 A1
(43) Pub. Date: Jul. 17, 2025

(54) SERVER CHASSIS

(71) Applicant: PEGATRON CORPORATION, TAIPEI CITY (TW)

(72) Inventor: Cheng-Wei Lin, TAIPEI CITY (TW)

(21) Appl. No.: 18/970,935

(22) Filed: Dec. 6, 2024

Related U.S. Application Data
(60) Provisional application No. 63/620,143, filed on Jan. 11, 2024.

(30) Foreign Application Priority Data
Apr. 24, 2024 (TW) 113204074

(51) Int. Cl. H05K 7/14; G06F 1/18

(52) U.S. Cl. CPC H05K 7/1489; G06F 1/187

(57) ABSTRACT

A server chassis includes a case body, a plurality of first longitudinal partitions, a first storage drive unit, and a second storage drive unit. The case body and the first longitudinal partitions jointly define a plurality of accommodating slots having a same width. The first storage drive unit includes a first storage drive and a first frame, and has a predetermined length and a predetermined width through cooperation therebetween. The second storage drive unit includes a second storage drive and a second frame, and has the predetermined length and the predetermined width through cooperation therebetween. A size of the second storage drive is different from a size of the first storage drive. Each of the first storage drive unit and the second storage drive unit is selectively installed in any one of the accommodating slots.

### CROSS-REFERENCE TO RELATED PATENT APPLICATION

This application claims the benefit of priorities to the U.S. Provisional Patent Application Ser. No. 63/620,143, filed on Jan. 11, 2024, and to Taiwan Patent Application No. 113204074, filed on Apr. 24, 2024. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a server chassis, and more particularly to a server chassis configured for accommodating a plurality of storage drives having different shapes and sizes.

### BACKGROUND OF THE DISCLOSURE

When multiple storage devices (e.g., storage drives) having different shapes and sizes are stored in a conventional server chassis, a diversity of cases are cooperatively designed according to different shapes and sizes of the multiple storage devices. Thus, the cases installed in the conventional server chassis are diverse. However, the diversity of the cases can lead to a difficult inventory management of the storage devices in the server chassis, and high mold costs can also be incurred for designing the diversity of the cases.

### SUMMARY OF THE DISCLOSURE

In response to the above-referenced technical inadequacies, the present disclosure provides a server chassis for effectively improving on the issues associated with a conventional server chassis.

In order to solve the above-mentioned problems, one of the technical aspects adopted by the present disclosure is to provide a server chassis. The server chassis includes a case body, a plurality of first longitudinal partitions arranged in the case body and spaced apart from each other, a first storage drive unit including a first storage drive and a first frame configured for fixing the first storage drive, and a second storage drive unit including a second storage drive and a second frame configured for fixing the second storage drive. The case body and the first longitudinal partitions jointly define a plurality of accommodating slots having a same width. The first storage drive unit has a predetermined length and a predetermined width through cooperation between the first frame and the first storage drive. A size of the second storage drive is different from a size of the first storage drive, and the second storage drive unit has the predetermined length and the predetermined width through cooperation between the second frame and the second storage drive. Each of the first storage drive unit and the second storage drive unit is selectively installed in any one of the accommodating slots.

Therefore, in the server chassis provided by the present disclosure, the first longitudinal partitions are modularized, and multiple storage devices (i.e., the first storage drive, the second storage drive, and the third storage drive) can be unified in shape and size through the first frame and the second frame. In this way, the multiple storage devices can cooperate with any of the first longitudinal partitions and be accommodated in the case body, thereby effectively reducing a component inventory and production costs of the server chassis.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a server chassis according to a first embodiment of the present disclosure;

FIG. 2 is a schematic perspective view showing a third storage drive unit of the server chassis exiting from a case body according to the first embodiment of the present disclosure;

FIG. 3 is a schematic exploded view of FIG. 1;

FIG. 4 is a schematic exploded view of a first storage drive unit according to the first embodiment of the present disclosure;

FIG. 5 is a schematic exploded view of a second storage drive unit according to the first embodiment of the present disclosure;

FIG. 6 is a schematic exploded view of a third storage drive unit according to the first embodiment of the present disclosure;

FIG. 7 is a schematic cross-sectional view taken along line VII-VII of FIG. 1;

FIG. 8 is a schematic perspective view of a server chassis according to a second embodiment of the present disclosure;

FIG. 9 is a schematic exploded view of FIG. 8;

FIG. 10 is a schematic exploded view of a compact disc (CD) drive unit according to the second embodiment of the present disclosure; and

FIG. 11 is a schematic perspective view showing the server chassis of FIG. 8 in another configuration.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case body of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

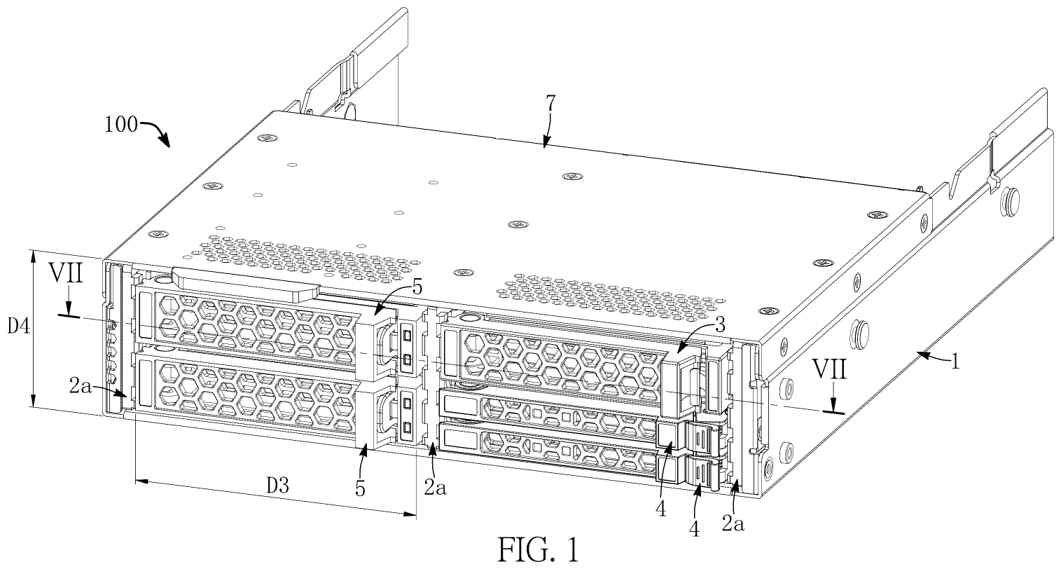

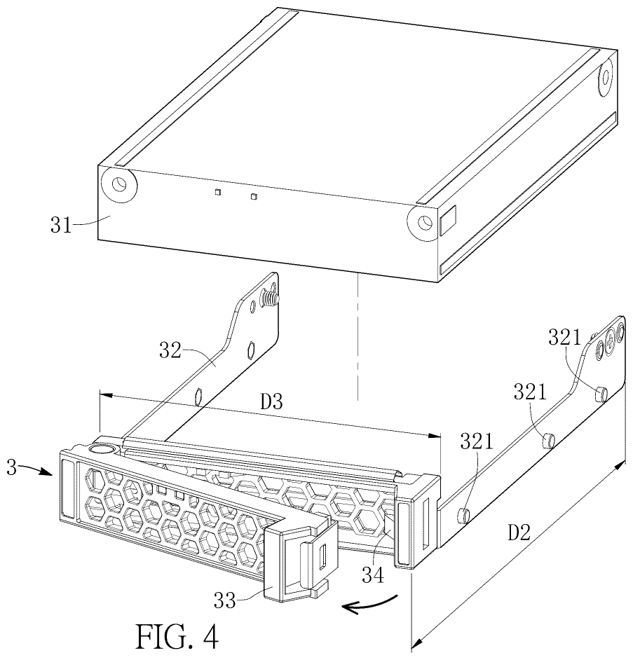

Referring to FIG. 1 to FIG. 7, a first embodiment of the present disclosure provides a server chassis 100. As shown in FIG. 1 to FIG. 3, in the present embodiment, the server chassis 100 includes a case body 1, a plurality of first longitudinal partitions 2a arranged in the case body 1 and spaced apart from each other, a first storage drive unit 3 accommodated in the case body 1, a plurality of (e.g., two) second storage drive units 4 accommodated in the case body 1, a plurality of (e.g., two) third storage drive units 5 accommodated in the case body 1, and a cover body 7 connected to the case body 1. In addition, although the server chassis 100 of the present embodiment includes the aforementioned components, the server chassis 100 can be adjusted or changed according to practical requirements and is not limited by the present embodiment. For example, in other embodiments of the present disclosure not shown in the drawings, the server chassis 100 can be provided without the third storage drive unit 5, a quantity of the second storage drive units 4 can be at least one, or a quantity of the third storage drive units 5 can be at least one.

It should be noted that the drawings only show a partial structure of the server chassis 100 for facilitating understanding of the present embodiment. A volume of the case body 1 of the server chassis 100 and a quantity of the first longitudinal partitions 2a of the server chassis 100 can be adjusted or changed according to practical requirements, and are not limited by the present embodiment.

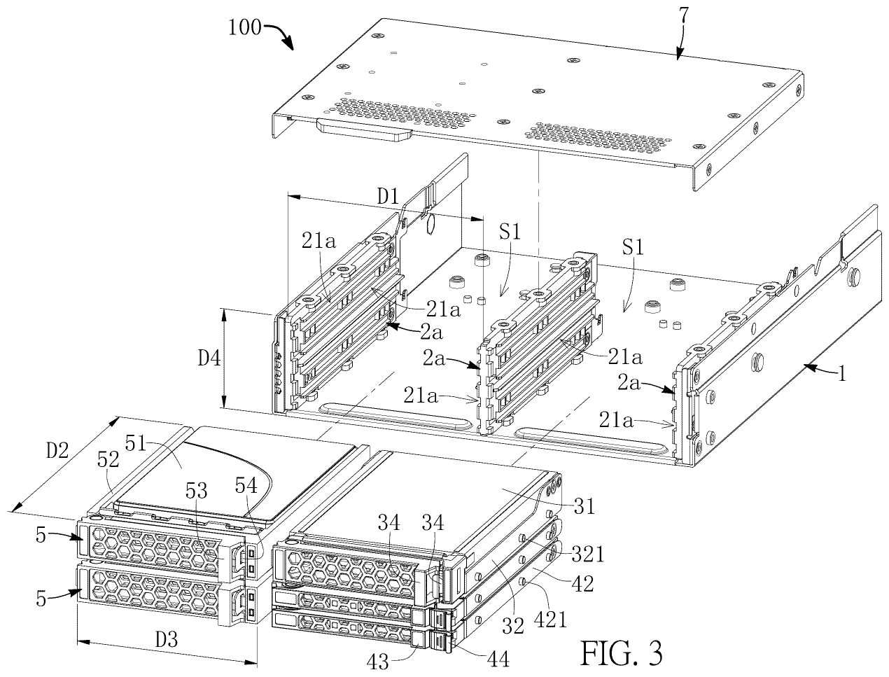

In the present embodiment, the case body 1 has a predetermined height D4, the quantity of the first longitudinal partitions 2a is exemplified to be three, and a height of each of the first longitudinal partitions 2a corresponds to (e.g., is substantially the same as) the predetermined height D4 of the case body 1. Specifically, the case body 1 and the first longitudinal partitions 2a jointly define a plurality of accommodating slots S1 having a same width (for example, as shown in FIG. 3, the three first longitudinal partitions 2a and the case body 1 can jointly define two accommodating slots S1). In other words, any two adjacent ones of the first longitudinal partitions 2a can define one of the accommodating slots S1, and each of the accommodating slots S1 has a width D1.

Moreover, any two of the first longitudinal partitions 2a adjacent to each other have two side walls that face toward each other and the two side walls respectively have a plurality of tracks 21a. It should be noted that a quantity of the tracks 21a can be designed to correspond to the height of each of the first longitudinal partitions 2a. That is to say, the quantity of the tracks 21a can be designed to correspond to the predetermined height D4. In the present embodiment, any two of the first longitudinal partitions adjacent to each other have the two side walls that face toward each other, each of the two side walls has four tracks 21a, and the four tracks 21a on one of the two side walls face toward and are parallel to the four tracks 21a on another one of the two side walls. However, the quantity of the tracks 21 can be adjusted or changed according to practical requirements, and is not limited by the present embodiment.

The aforementioned description describes structures and cooperation of the case body 1 and each of the first longitudinal partitions 2a provided in the present embodiment. The following description describes other components of the server chassis 100 and connection relationships thereof.

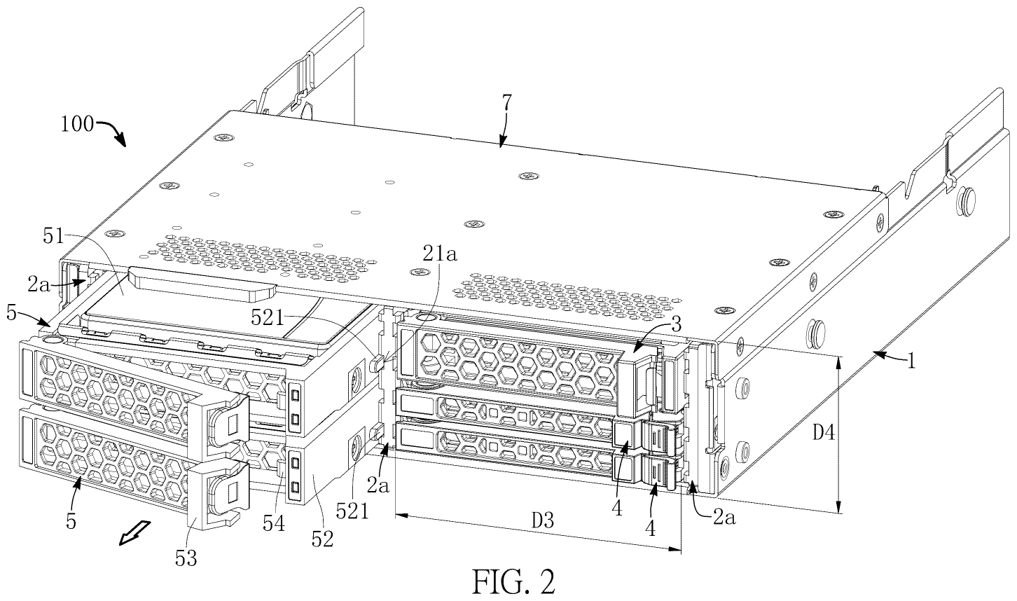

As shown in FIG. 2 and FIG. 3, the first storage drive unit 3, the two second storage drive units 4, and the two third storage drive units 5 are accommodated in the two accommodating slots S1 that are jointly defined by the case body 1 and the three first longitudinal partitions 2a. Specifically, the first storage drive unit 3, the two second storage drive units 4, and the two third storage drive units 5 are (slidably) installed into the two accommodating slots S1 through the tracks 21a of the first longitudinal partitions 2a.

It should be noted that each of the tracks 21a of the first longitudinal partitions 2a can be provided for installation of the first storage drive unit 3, one of the second storage drive units 4, or one of the third storage drive units 5. In the present embodiment, one of the first longitudinal partitions 2a can be provided for installation of the two third storage drive units 5, and can also be provided for installation of the first storage drive unit 3 and the two second storage drive units 4.

Specifically, a height of the first storage drive unit 3 is the same as a height of each of the third storage drive units 5. The height of the first storage drive unit 3 is twice a height of each of the second storage drive units 4. The height of each of the third storage drive units 5 is twice the height of each of the second storage drive units 4. Accordingly, the predetermined height D4 of the case body 1 can be a multiple of the height of the first storage drive unit 3, a multiple of the height of each of the second storage drive units 4, or a multiple of the height of each of the third storage drive units 5.

The aforementioned description describes the connection relationships of the main components of the server chassis 100. The following description describes inner structures of the first storage drive unit 3, each of the second storage drive units 4, and each of the third second storage drive units 5, and their cooperative relationships with the first longitudinal partitions 2a.

As shown in FIG. 2 to FIG. 4, the first storage drive unit 3 has a predetermined length D2 and a predetermined width D3. The predetermined length D2 is preferably within a range from 130 mm to 135 mm, and the predetermined width D3 is preferably within a range from 75 mm to 85 mm. It should be noted that the predetermined width D3 is the same as the width D1 of any one of the accommodating slots S1, so that the first storage drive unit 3 can be completely compatible with any one of the accommodating slots S1.

The first storage drive unit 3 includes a first storage drive 31, a first frame 32 configured for fixing the first storage drive 31, a first handle 33 pivotally connected to one side of the first frame 32, and a first buckle 34 connected to another one side of the first frame 32. In the present embodiment, the first storage drive 31 is exemplified as an E3.S 2 T solid-state drive (SSD), but the present disclosure is not limited thereto.

Furthermore, the first storage drive unit 3 has the predetermined length D2 and the predetermined width D3 through cooperation between the first frame 32 and the first storage drive 31. More specifically, in order that the first storage drive unit 3 has the predetermined length D2 and the predetermined width D3, the first frame 32 is substantially a U-shaped frame that covers a lateral edge of the first storage drive 31 (i.e., three surface of the first storage drive 31).

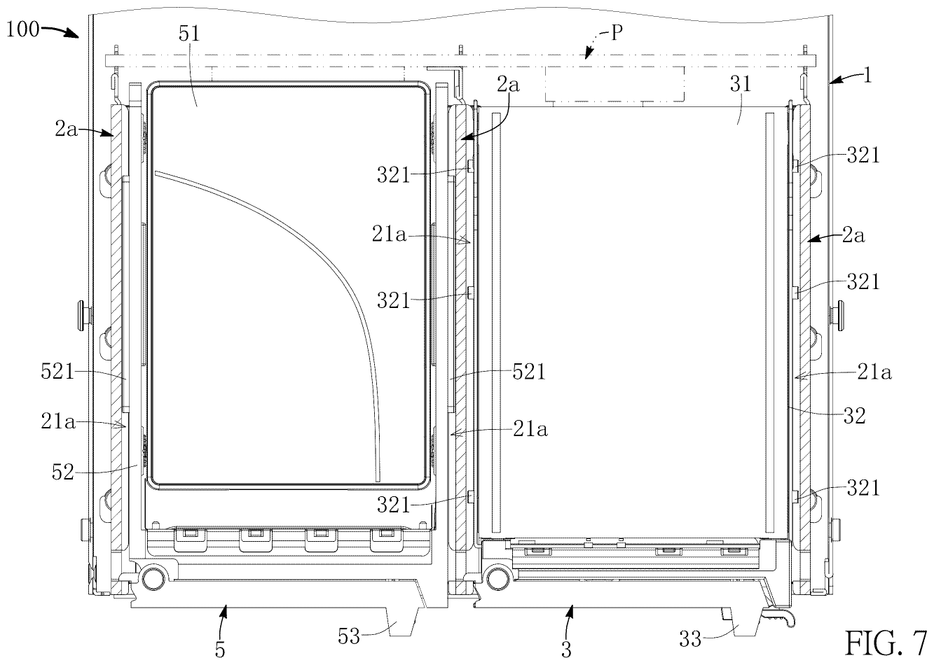

A plurality of protrusion portions 321 are formed on each of two outer sides of the first frame 32. When the first storage drive unit 3 is installed in one of the accommodating slots S1, the protrusion portions 321 on one of the two outer sides of the first frame 32 are disposed in one of the tracks 21a of a corresponding one of the first longitudinal partitions 2a (e.g., as shown in FIG. 3 and FIG. 7). In the present embodiment, each of the protrusion portions 321 of the first frame 32 has a circular protrusion shape, but the shape of each of the protrusion portions 321 can be adjusted or changed relative to the tracks 21a of the first longitudinal partitions 2a according to practical requirements. The specific shape of each of the protrusion portions 321 is not limited by the present embodiment.

Moreover, the first handle 33 is pivotally connected to the one side of the first frame 32, and the first buckle 34 is connected to the another one side of the first frame 32. The first handle 33 can be fixed to the first frame 32 by engaging with the first buckle 34, so as to prevent the first storage drive unit 3 from falling out of one of the accommodating slots S1. In addition, the first handle 33 can rotate relative to the first frame 32 by an angle (which is preferably within a range from 30° to 89°). After the first handle 33 is rotated and detached from the first buckle 34, a user can conveniently pull out the first storage drive unit 3 from one of the accommodating slots S1.

In detail, the user can easily install the first storage drive unit 3 into one of the accommodating slots S1 or pull out the first storage drive unit 3 from one of the accommodating slots S1 through the first handle 33. After the first storage drive unit 3 is installed in one of the accommodating slots S1, the first handle 33 can be fixed to the first frame 32 through the first buckle 34, so that the first storage drive unit 3 can be limited in one of the accommodating slots S1.

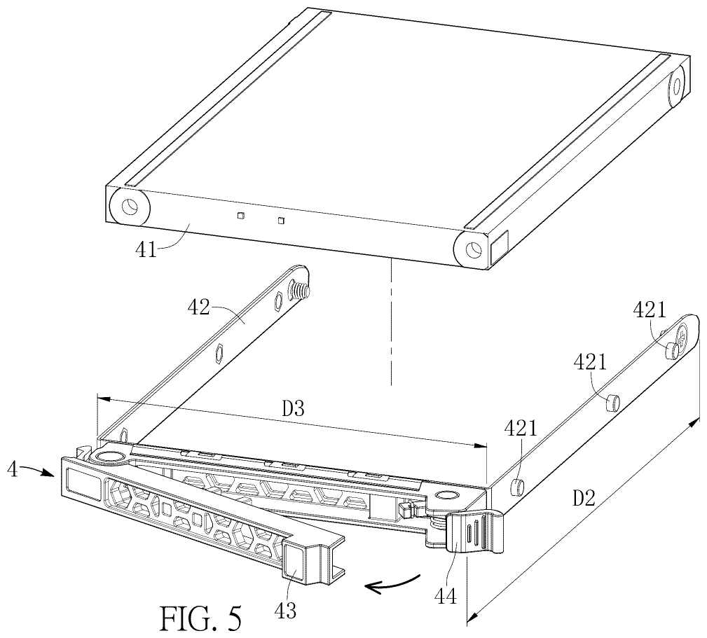

As shown in FIG. 2, FIG. 3, and FIG. 5, each of the second storage drive units 4 also has the predetermined length D2 and the predetermined width D3. Each of the second storage drive units 4 includes a second storage drive 41, a second frame 42 configured for fixing the second storage drive 41, a second handle 43 pivotally connected to one side of the second frame 42, and a second buckle 44 connected to another one side of the second frame 42. In the present embodiment, the second storage drive 41 is exemplified as an E3.S 1 T solid-state drive (SSD), but the present disclosure is not limited thereto.

It should be noted that a size of the second storage drive 41 is different from a size of the first storage drive 31. However, through cooperation between the second frame 42 and the second storage drive 41, each of the second storage drive units 4 can have the predetermined length D2 and the predetermined width D3 of the first storage drive unit 3. Specifically, in order that the second storage drive unit 4 has the predetermined length D2 and the predetermined width D3, the second frame 42 is substantially a U-shaped frame that covers a lateral edge of the second storage drive 41 (i.e., three surface of the second storage drive 41).

A plurality of protrusion portions 421 are formed on each of two outer sides of the second frame 42. When one of the second storage drive units 4 is installed in one of the accommodating slots S1, the protrusion portions 421 on one of the two outer sides of the second frame 42 are disposed in one of the tracks 21a of a corresponding one of the first longitudinal partitions 2a (e.g., a configuration of the second frame 42 and the first longitudinal partitions 2a is substantially the same as a configuration of the first frame 32 and the first longitudinal partitions 2a that is shown in FIG. 7). In the present embodiment, each of the protrusion portions 421 of the second frame 42 has a circular protrusion shape, but the shape of each of the protrusion portions 421 can be adjusted or changed relative to the tracks 21a of the first longitudinal partitions 2a according to practical requirements.

Moreover, the second handle 43 is pivotally connected to the one side of the second frame 42, and the second buckle 44 is connected to the another one side of the second frame 42. The second handle 43 can be fixed to the second frame 42 by engaging with the second buckle 44, so as to prevent each of the second storage drive units 4 from falling out of one of the accommodating slots S1. In addition, the second handle 43 can rotate relative to the second frame 42 by an angle (which is preferably within a range from 30° to 89°). After the second handle 43 is rotated and detached from the second buckle 44, the user can conveniently pull out one of the second storage drive units 4 from one of the accommodating slots S1.

In detail, the user can easily install one of the second storage drive units 4 into one of the accommodating slots S1 or pull out one of the second storage drive units 4 from one of the accommodating slots S1 through the second handle 43. After one of the second storage drive units 4 is installed in one of the accommodating slots S1, the second handle 43 can be fixed to the second frame 42 through the second buckle 44, so that one of the second storage drive units 4 can be limited in one of the accommodating slots S1.

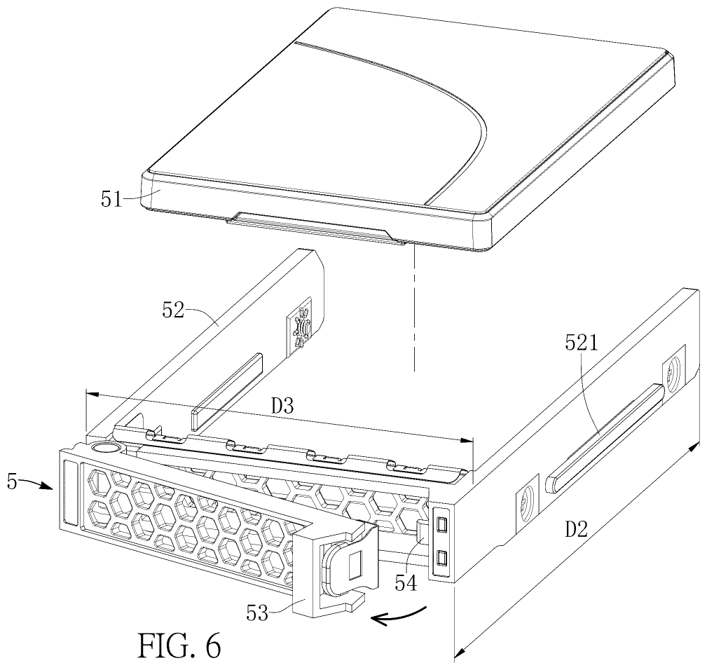

As shown in FIG. 2, FIG. 3, and FIG. 6, each of the third storage drive units 5 similarly has the predetermined length D2 and the predetermined width D3. Each of the third storage drive units 5 includes a third storage drive 51, a third frame 52 configured for fixing the third storage drive 51, a third handle 53 pivotally connected to an outer side of the third frame 52, and a third buckle 54 connected to the third frame 52. In the present embodiment, the third storage drive 51 is exemplified as a 2.5-inch hard disk drive (HDD), but the present disclosure is not limited thereto.

It should be noted that a size of the third storage drive 51 is different from the size of the first storage drive 31 and the size of the second storage drive 41. However, through cooperation between the third frame 52 and the third storage drive 51, each of the third storage drive units 5 can have the predetermined length D2 and the predetermined width D3 of the first storage drive unit 3. Specifically, in order that the third storage drive unit 5 has the predetermined length D2 and the predetermined width D3, the third frame 52 is substantially a U-shaped frame that covers a lateral edge of the third storage drive 51 (i.e., three surface of the third storage drive 51).

A strip-shaped protrusion portion 521 is formed on each of two outer sides of the third frame 52. When one of the third storage drive units 5 is installed in one of the accommodating slots S1, the protrusion portion 521 on one of the two outer sides of third frame 52 is disposed in one of the tracks 21a of a corresponding one of the first longitudinal partitions 2a (e.g., as shown in FIG. 2, FIG. 3, and FIG. 7). In the present embodiment, each of the protrusion portions 521 is a transverse protrusion, but the shape of each of the protrusion portions 521 can be adjusted or changed relative to the tracks 21a of the first longitudinal partitions 2a according to practical requirements.

The third handle 53 is pivotally connected to one side of the third frame 52, and the third buckle 54 is connected to another one side of the third frame 52. The third handle 53 can be fixed to the third frame 52 by engaging with the third buckle 54, so as to prevent each of the third storage drive units 5 from falling out of one of the accommodating slots S1. Moreover, the third handle 53 can rotate relative to the third frame 52 by an angle (which is preferably within a range from 30° to 89°). After the third handle 53 is rotated and detached from the third buckle 54, the user can conveniently pull out one of the third storage drive units 5 from one of the accommodating slots S1.

In detail, the user can easily install one of the third storage drive units 5 into one of the accommodating slots S1 or pull out one of the third storage drive units 5 from one of the accommodating slots S1 through the third handle 53. After one of the third storage drive units 5 is installed in one of the accommodating slots S1, the third handle 53 can be fixed to the third frame 52 through the third buckle 54, so that one of the third storage drive units 5 can be limited in one of the accommodating slots S1.

Accordingly, each of the first storage drive unit 3, the second storage drive units 4, and the third storage drive units 5 of the present embodiment have the predetermined length D2 and the predetermined width D3, and thus can be selectively installed in any one of the accommodating slots S1.

In other words, the first storage drive unit 3, the second storage drive units 4, or the third storage drive units 5 can be arbitrarily installed in any one of the accommodating slots S1. In the present embodiment, as shown in FIG. 1 to FIG. 3, one of the two accommodating slots S1 accommodates the two third storage drive units 5, and another one of the two accommodating slots S1 accommodates the first storage drive unit 3 and the two second storage drive units 4. However, a combination of the first storage drive unit 3, the second storage drive units 4, or the third storage drive units 5 that are installed in any one of the accommodating slots S1 can be adjusted or changed according to practical requirements, and is not limited by the present embodiment. For example, one of the accommodating slots S1 can be provided for accommodating only one of the first storage drive unit 3, the second storage drive units 4, or the third storage drive units 5.

Accordingly, in the server chassis 100 provided by the present disclosure, the first longitudinal partitions 2a are modularized, and the first storage drive 31, the second storage drive 41, and the third storage drive 51 can be unified in shape and size through the first frame 32, the second frame 42, and the third frame 52. In this way, the first storage drive unit 3, each of the second storage drive units 4, or each of the third storage drive units 5 can cooperate with any one of the first longitudinal partitions 2a and be installed in any of the accommodating slots S1.

It should be noted that, due to having the predetermined length D2 and the predetermined width D3, the first storage drive unit 3, each of the second storage drive units 4, and each of the third storage drive units 5 can be completely compatible with any one of the accommodating slots S1. In addition, a rear end of the first storage drive 31, the second storage drive 41, and the third storage drive 51 can be detachably plugged on a backplane P (as shown in FIG. 7) through a connection assembly, but the present disclosure is not limited thereto. For example, in other embodiments of the present disclosure not shown in the drawings, the rear end of the first storage drive 31, the second storage drive 41, and the third storage drive 51 can be detachably plugged on different ones of the backplane P according to practical requirements.

### Second Embodiment

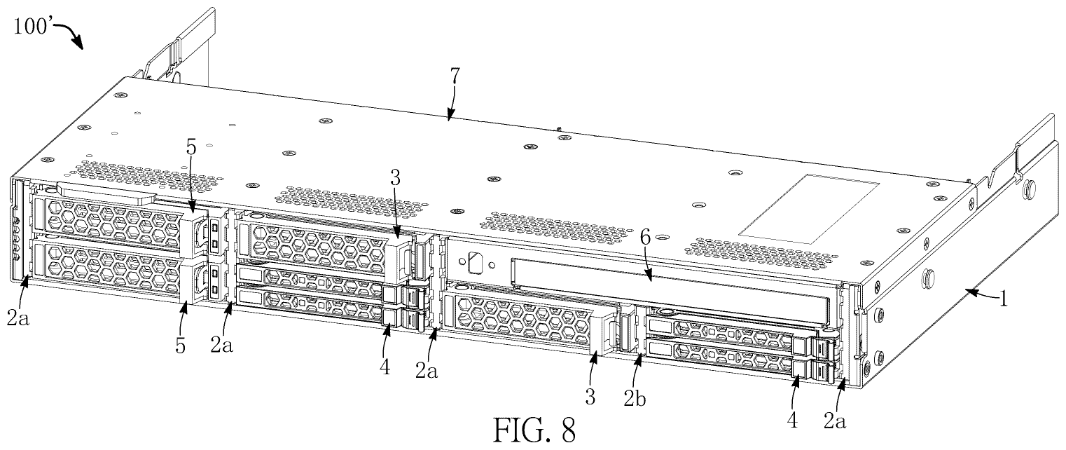

Referring to FIG. 8 to FIG. 11, a second embodiment of the present disclosure provides a server chassis 100′. As shown in FIG. 8, the server chassis 100′ of the present embodiment includes the server chassis 100 of the first embodiment and an additional section that extends outward from the server chassis 100. The present embodiment is similar to the first embodiment, and their similarities will not be reiterated herein. Compared with the first embodiment, the server chassis 100′ of the present embodiment not only includes the additional section but can also accommodate a compact disc (CD) drive unit 6.

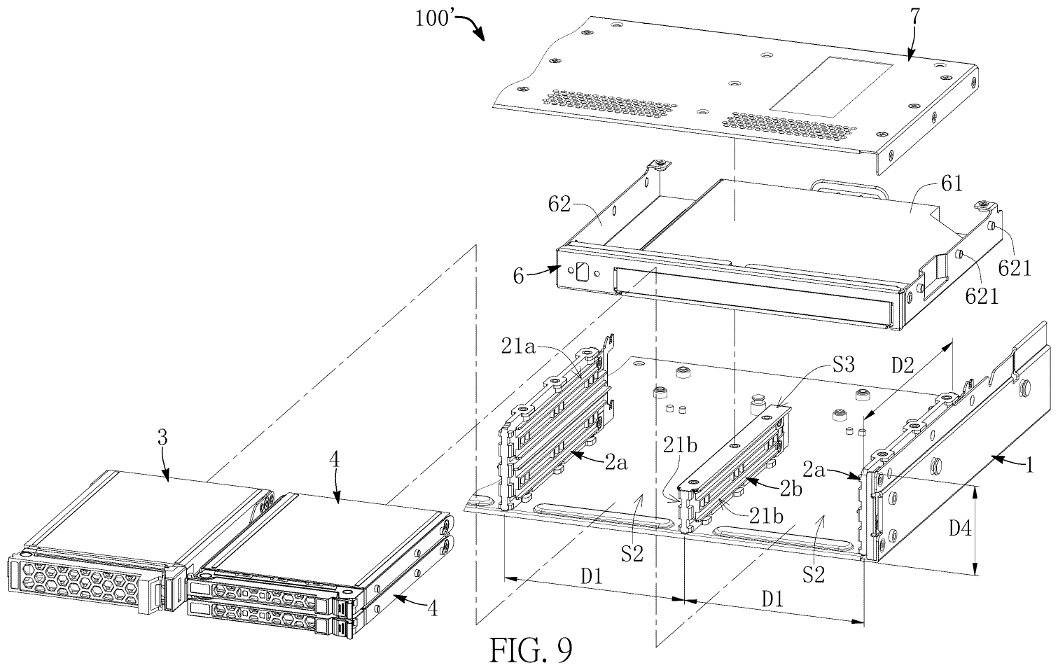

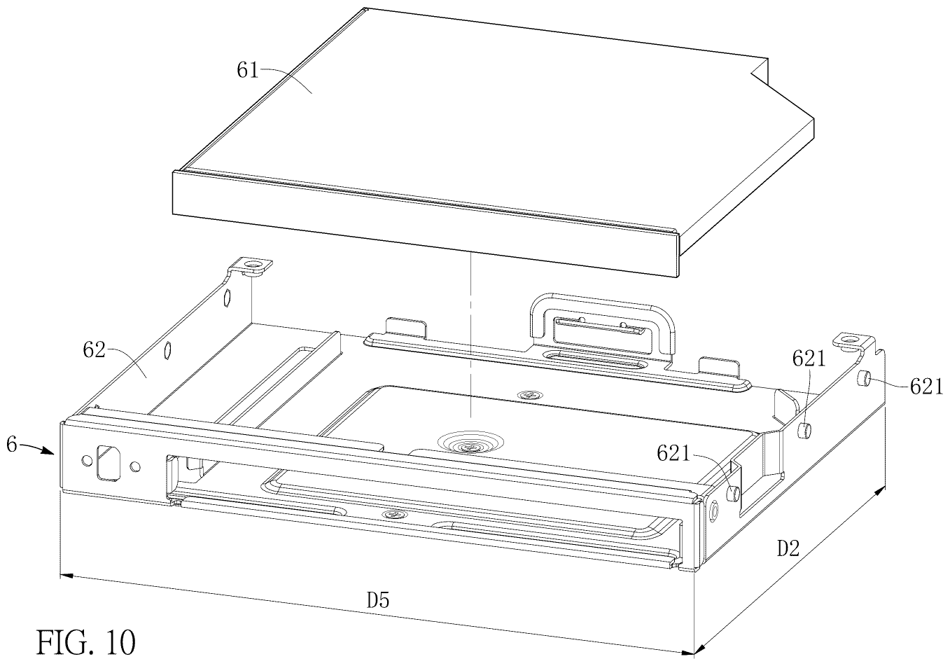

As shown in FIG. 9 and FIG. 10, the server chassis 100′ further includes the CD drive unit 6 and a second longitudinal partition 2b, and the second longitudinal partition 2b is arranged in the case body 1 and is spaced apart from the first longitudinal partitions 2a. Specifically, a structure of the second longitudinal partition 2b is substantially the same as a structure of any one of the first longitudinal partitions 2a. The difference between the second longitudinal partition 2b and the first longitudinal partitions 2a is that a height of the second longitudinal partition 2b is less than the height of any one of the first longitudinal partitions 2a.

Two of the first longitudinal partitions 2a that are adjacent to the second longitudinal partition 2b and the second longitudinal partition 2b are spaced apart from each other, thereby dividing the case body 1 into two storage drive accommodating slots S2. Moreover, two of the first longitudinal partitions 2a that are adjacent to the second longitudinal partition 2b and the second longitudinal partition 2b can jointly define a CD drive accommodating slot S3.

Each of two side walls of the second longitudinal partition 2b includes two tracks 21b. Each of the two storage drive accommodating slots S2 is equivalent to any one of the accommodating slots S1 of the first embodiment. That is to say, the first storage drive unit 3, the second storage drive unit 4, or the third storage drive unit 5 can be (slidably) installed into each of the two storage drive accommodating slots S2.

In the present embodiment, as shown in FIG. 9, the first storage drive unit 3 is accommodated in one of the two storage drive accommodating slots S2, and two of the second storage drive units 4 are accommodated in another one of the two storage drive accommodating slots S2. However, the first storage drive unit 3, the second storage drive unit 4, or the third storage drive unit 5 can be selectively installed in the two storage drive accommodating slots S2 according to practical requirements, and the present disclosure is not limited thereto.

Moreover, as shown in FIG. 9 and FIG. 10, a width of the CD drive accommodating slot S3 is approximately twice the width D1 of the accommodating slots S1 of the first embodiment, and the CD drive accommodating slot S3 is configured to accommodate the CD drive unit 6. The CD drive unit 6 includes a CD drive 61 and a CD drive carrier 62 that carries the CD drive 61, and the CD drive unit 6 has the predetermined length D2 and twice the predetermined width D3 through cooperation between the CD drive carrier 62 and the CD drive 61.

In other words, the CD drive unit 6 has a width D5 (i.e., twice the predetermined width D3) that is the same as the width of the CD drive accommodating slot S3, so that the CD drive unit 6 can be completely compatible with the CD drive accommodating slot S3. Specifically, in order that the CD drive 61 has the predetermined length D2 and twice the predetermined width D3, the CD drive carrier 62 is substantially a cubical case to hold the CD drive 61.

A plurality of protrusion portions 621 are formed on each of two outer sides of the CD drive carrier 62. When the CD drive unit 6 is installed in the CD drive accommodating slot S3, the protrusion portions 621 on one of the two outer sides of the CD drive carrier 62 are disposed in one of the tracks 21a of a corresponding one of the first longitudinal partitions 2a. In the present embodiment, each of the protrusion portions 621 of the CD drive carrier 62 has a circular protrusion shape, but the shape of each of the protrusion portions 621 can be adjusted or changed relative to the tracks 21a of the first longitudinal partitions 2a according to practical requirements.

In other words, as shown in FIG. 8 to FIG. 10, the CD drive unit 6 installed in the CD drive accommodating slot S3 can be directly disposed on (or fixed to) the second longitudinal partition 2b. Accordingly, apart from accommodating the first storage drive unit 3, the second storage drive unit 4, and the third storage drive unit 5, the server chassis 100′ of the present embodiment can further accommodate the CD drive unit 6 through a configuration of the second longitudinal partition 2b.

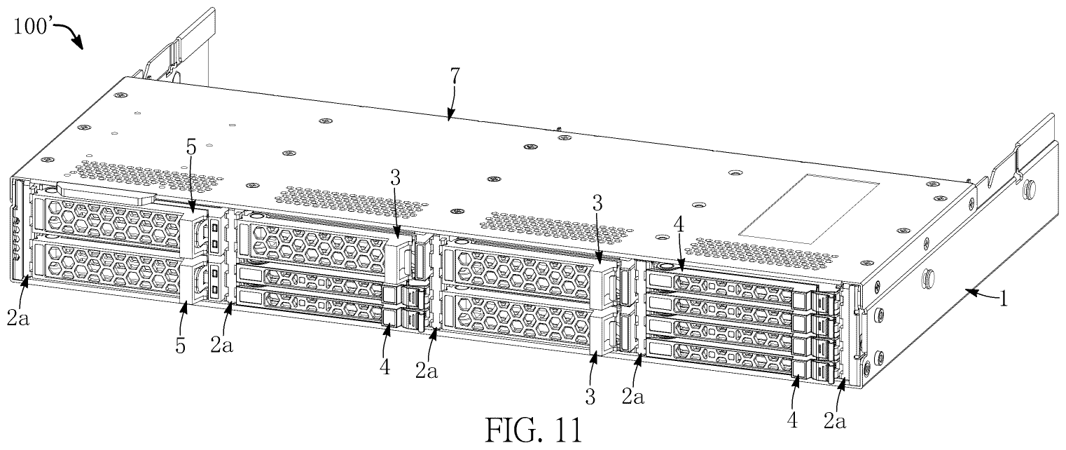

In addition, the additional section of the server chassis 100′ can be configured for assembling components according to practical requirements. For example, as shown in FIG. 11, the server chassis 100′ does not include the CD drive unit 6, and one of the first longitudinal partitions 2a can be used to replace the second longitudinal partition 2b according to practical requirements. Similarly, this first longitudinal partition 2a can cooperate with two adjacent ones of the first longitudinal partitions 2a, thereby jointly defining the two accommodating slots S1 that are configured for accommodating the first storage drive unit 3, the second storage drive unit 4, or the third storage drive unit 5. That is to say, the components installed in any one of the accommodating slots S1 can be any arrangement of the first storage drive unit 3, the second storage drive unit 4, and the third storage drive unit 5, and the present disclosure is not limited thereto.

### Beneficial Effects of the Embodiments

In conclusion, in the server chassis provided by the present disclosure, the first longitudinal partitions are modularized, and multiple storage devices (i.e., the first storage drive, the second storage drive, and the third storage drive) can be unified in shape and size through the first frame, the second frame, and the third frame. In this way, the multiple storage devices can cooperate with any one of the first longitudinal partitions and be accommodated in the case body, thereby effectively reducing a component inventory and production costs of the server chassis.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A server chassis, comprising:
a case body;
a plurality of first longitudinal partitions arranged in the case body and spaced apart from each other, wherein the case body and the first longitudinal partitions jointly define a plurality of accommodating slots having a same width;
a first storage drive unit including a first storage drive and a first frame configured for fixing the first storage drive, wherein the first storage drive unit has a predetermined length and a predetermined width through cooperation between the first frame and the first storage drive; and
a second storage drive unit including a second storage drive and a second frame configured for fixing the second storage drive, wherein a size of the second storage drive is different from a size of the first storage drive, and the second storage drive unit has the predetermined length and the predetermined width through cooperation between the second frame and the second storage drive;
wherein each of the first storage drive unit and the second storage drive unit is selectively installed in any one of the accommodating slots.

2. The server chassis according to claim 1, further comprising a third storage drive unit, wherein the third storage drive unit includes a third storage drive and a third frame configured for fixing the third storage drive, and the third storage drive unit has the predetermined length and the predetermined width through cooperation between the third frame and the third storage drive, and wherein the third storage drive is selectively installed in any one of the accommodating slots.

3. The server chassis according to claim 2, wherein the first storage drive is an E3.S 2 T solid-state drive (SSD), the second storage drive is an E3.S 1 T solid-state drive, and the third storage drive is a 2.5-inch hard disk drive (HDD).

4. The server chassis according to claim 1, wherein the first storage drive unit further includes:
a first handle pivotally connected to one side of the first frame, wherein the first handle is rotatable to enable the first storage drive unit to exit one of the accommodating slots; and
a first buckle connected to another one side of the first frame, wherein the first buckle is configured to hold the first handle, and the first buckle is configured to fix the first handle to the first frame.

5. The server chassis according to claim 1, wherein the second storage drive unit further includes:
a second handle pivotally connected to one side of the second frame, wherein the second handle is rotatable to enable the second storage drive unit to exit one of the accommodating slots; and
a second buckle connected to another one side of the second frame, wherein the second buckle is configured to hold the second handle, and the second buckle is configured to fix the second handle to the second frame.

6. The server chassis according to claim 1, wherein two outer sides of the first frame and two outer sides of the second frame respectively include a plurality of protrusion portions, and any two of the first longitudinal partitions adjacent to each other have two side walls that face toward each other and the two side walls respectively have a plurality of tracks, and wherein, when any one of the first storage drive unit and the second storage drive unit is installed in one of the accommodating slots, the protrusion portions are respectively and correspondingly disposed in the tracks of the first longitudinal partitions.

7. The server chassis according to claim 1, wherein the predetermined length is within a range from 130 mm to 135 mm, and the predetermined width is within a range from 75 mm to 85 mm.

8. The server chassis according to claim 1, wherein the case body has a predetermined height, and wherein the predetermined height is a multiple of a height of the first storage drive unit, and the predetermined height is a multiple of a height of the second storage drive unit.

9. The server chassis according to claim 1, further comprising a second longitudinal partition, wherein the second longitudinal partition is arranged in the case body and is spaced apart from the first longitudinal partitions, and a height of the second longitudinal partition is less than a height of any one of the first longitudinal partitions.

10. The server chassis according to claim 9, further comprising a compact disc (CD) drive unit, wherein the CD drive unit includes a CD drive and a CD drive carrier that carries the CD drive, and the CD drive unit has the predetermined length and twice the predetermined width through cooperation between the CD drive carrier and the CD drive.
